(19) United States
(12) Patent Application Publication
(10) Pub. No.: US 2024/0357747 A1
(43) Pub. Date: Oct. 24, 2024

(54) METHODS OF PACKAGING MICROELECTRONIC DEVICES UTILIZING PANELS AND RELATED TEMPORARY STRUCTURES

(71) Applicant: Microchip Technology Incorporated, Chandler, AZ (US)

(72) Inventor: J. Andrew Kovats, Manitou Springs, CO (US)

(21) Appl. No.: 18/354,559

(22) Filed: Jul. 18, 2023

Related U.S. Application Data
(60) Provisional application No. 63/497,134, filed on Apr. 19, 2023.

(51) Int. Cl. H05K 1/18; H05K 1/11; H05K 5/00

(52) U.S. Cl. CPC H05K 1/181; H05K 1/115; H05K 5/0091; H05K 2201/10674

(57) ABSTRACT

Methods may involve supporting a plurality of microelectronic dice on a printed circuit panel. Respective microelectronic dice of the plurality of microelectronic dice may be electrically connected to at least one via of the printed circuit panel. Microelectronic device packages may be singulated from the printed circuit panel, respective microelectronic device packages including at least one microelectronic die of the plurality of microelectronic dice and a portion of the printed circuit panel. Structures may include a plurality of microelectronic dice supported on a printed circuit panel. The printed circuit panel may include vias, subsets of the vias positioned for electrical connection to a respective microelectronic die of the plurality of microelectronic dice.

### CROSS-REFERENCE TO RELATED APPLICATIONS

This application claims the benefit under 35 U.S.C. § 119 (e) of U.S. Provisional Patent Application Ser. No. 63/497,134, filed Apr. 19, 2023, for, “Methods of Packaging Microelectronic Devices Utilizing Panels and Related Temporary Structures,” the disclosure of which is incorporated herein in its entirety by this reference.

### FIELD

This disclosure relates generally to methods of packaging microelectronic devices utilizing panels and related temporary structures. More specifically, disclosed examples relate to microelectronic device packaging techniques which may reduce cost and waste, increase reliability and yield, and involve performance of fewer process steps when compared to panel-level packaging techniques known to the inventor.

### BACKGROUND

The inventor is aware of some attempts to package microelectronic devices at the panel level. Generally, these techniques may involve singulating microelectronic devices from wafers, arranging the microelectronic devices in an array within a rectangular or square border, and capturing the microelectronic devices in a dielectric material to form a panel. The panel including the microelectronic devices may be supported on a rigid carrier, such as a stainless steel or glass carrier. Following panel formation, additional processing may be performed on the microelectronic devices, such as signal routing (e.g., fan-out processes). The carrier may be removed before singulation of individual microelectronic device packages from the panel.

### BRIEF SUMMARY

In some examples, methods may involve supporting a plurality of microelectronic dice on a printed circuit panel. Respective microelectronic dice of the plurality of microelectronic dice may be electronically connected to at least one via of the printed circuit panel. Microelectronic device packages may be singulated from the printed circuit panel, respective microelectronic device packages including at least one microelectronic die of the plurality of microelectronic dice and a portion of the printed circuit panel.

In other examples, temporary structures may include a plurality of microelectronic dice supported on a printed circuit panel. The printed circuit panel may include vias, subsets of the vias positioned for electrical connection to a respective microelectronic die of the plurality of microelectronic dice.

In other examples, methods may involve forming a redistribution layer on a printed circuit panel, and in connection with vias of the printed circuit panel. A plurality of microelectronic dice may be supported on the redistribution layer. Respective microelectronic dice of the plurality of microelectronic dice may be electronically connected to the redistribution layer. Microelectronic device packages may be singulated from the printed circuit panel, respective microelectronic device packages including at least one microelectronic die of the plurality of microelectronic dice and a portion of the printed circuit panel.

### BRIEF DESCRIPTION OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings. In the drawings:

FIG. 1 is a flowchart of a method of packaging microelectronic devices;

FIG. 2 is a flowchart of another method of packaging microelectronic devices;

FIG. 3 is a surface view of a printed circuit panel;

FIG. 4 is a cross-sectional side view of a portion of the printed circuit panel of FIG. 3;

FIG. 5 is a cross-sectional side view of a temporary structure in a first stage of either of the methods of FIG. 1 or FIG. 2;

FIG. 6 is a cross-sectional side view of a microelectronic die;

FIG. 7 is a cross-sectional side view of another temporary structure in a second stage of the method of FIG. 1 or FIG. 2;

FIG. 8 is a cross-sectional side view of another temporary structure in a third stage of the method of FIG. 1 or FIG. 2;

FIG. 9 is a cross-sectional side view of a microelectronic device package;

FIG. 10 is a flowchart of another method of packaging microelectronic devices;

FIG. 11 is a cross-sectional side view of a temporary structure in a first stage of the method of FIG. 1 or FIG. 10;

FIG. 12 is a cross-sectional side view of another microelectronic die;

FIG. 13 is a cross-sectional side view of another temporary structure in a second stage of the method of FIG. 1 or FIG. 10;

FIG. 14 is a cross-sectional side view of another temporary structure in a third stage of the method of FIG. 1 or FIG. 10;

FIG. 15 is a cross-sectional side view of another temporary structure in a fourth stage of the method of FIG. 1 or FIG. 10;

FIG. 16 is a cross-sectional side view of another temporary structure in a fifth stage of the method of FIG. 1 or FIG. 10;

FIG. 17 is a flowchart of another method of packaging microelectronic devices;

FIG. 18 is a surface view of another microelectronic device package;

FIG. 19 is a cross-sectional view of a portion of another printed circuit panel;

FIG. 20 is a cross-sectional side view of a temporary structure in a first stage of the method of FIG. 1 or FIG. 17;

FIG. 21 is a cross-sectional side view of another temporary structure in a second stage of the method of FIG. 1 or FIG. 17; and

FIG. 22 is a flowchart of another method of packaging microelectronic devices.

### DETAILED DESCRIPTION

The illustrations presented in this disclosure are not meant to be actual views of any particular printed circuit panel, microelectronic device, microelectronic device package, temporary structure in a process of making microelectronic device packages, or component thereof, but are merely idealized representations employed to describe illustrative examples. Thus, the drawings are not necessarily to scale.

Disclosed examples relate generally to techniques for packaging microelectronic devices utilizing printed circuit panels. Such techniques may reduce cost and waste, increase reliability and yield, and involve fewer process steps when compared to panel-level packaging techniques known to the inventor. More specifically, disclosed are examples of printed circuit panels and methods of utilizing printed circuit panels to produce multiple microelectronic device packages. For example, methods of making microelectronic device packages in accordance with this disclosure may involve supporting a plurality of microelectronic dice on a printed circuit panel. Respective microelectronic dice of the plurality of microelectronic dice may be electrically connected to at least one via of the printed circuit panel. Microelectronic device packages may be singulated from the printed circuit panel, with respective microelectronic device packages including at least one microelectronic die of the plurality of microelectronic dice and a portion of the printed circuit panel.

In some examples, the packaging techniques may involve forming a redistribution layer on the printed circuit panel, and in connection with the vias, before supporting the plurality of microelectronic dice on the printed circuit panel. In such examples, supporting the plurality of microelectronic dice on the printed circuit panel may involve supporting the plurality of microelectronic dice on the redistribution layer. Forming the redistribution layer may be accomplished, for example, by positioning electrically conductive material of the redistribution layer on regions of the printed circuit panel between the vias. Electrically connecting respective microelectronic dice of the plurality of microelectronic dice to the at least one via of the printed circuit panel may involve, for example, reflowing electrically conductive material extending from respective microelectronic dice of the plurality of microelectronic dice to the redistribution layer. More specifically, reflowing the electrically conductive material may be accomplished by, for example, directing energy emitted from a laser toward the electrically conductive material to reflow the electrically conductive material. In some examples consistent with the foregoing, the plurality of microelectronic dice may be placed in flip-chip orientations when supporting the plurality of microelectronic dice on the printed circuit panel.

In other examples, active surfaces of the plurality of microelectronic dice may be positioned on sides of the plurality of microelectronic dice to face away from the printed circuit panel when supporting the plurality of microelectronic dice on the printed circuit panel. A first redistribution layer may be formed on the printed circuit panel, and in electrical connection with the vias, before supporting the plurality of microelectronic dice on the printed circuit panel. The first redistribution layer may include studs of electrically conductive material, the studs having a height above the printed circuit panel at least at great as a greatest thicknesses of any microelectronic die of the plurality of microelectronic dice. The plurality of microelectronic dice may be supported on portions of the redistribution layer between the studs. In some examples, a molding material may be placed around the plurality of microelectronic devices and around at least portions of the studs. A second redistribution layer may be formed on the molding material, in electrical connection with the studs, and in electrical connection with the plurality of microelectronic devices. A passivation material may cover the second redistribution layer.

In some examples, singulating the microelectronic device packages from the printed circuit panel may involve singulating the microelectronic device packages such that at least some of the microelectronic device packages comprise bond pads located on a side of at least some of the microelectronic device packages facing away from the microelectronic device and located along respective sides of peripheries of at least some of the microelectronic device packages. In other examples, singulating the microelectronic device packages from the printed circuit panel may involve singulating the microelectronic device packages such that at least some of the microelectronic device packages comprise bond pads arranged in grid.

In some illustrative methods, wire bonds may not be required, steel or glass carriers may not be required, carrier debond processes may not be required, or any combination or subcombination of these processes may be omitted. In some illustrative methods, processes involving wire bonding, steel or glass carriers, or carrier debond, may not be required, nor any combination nor subcombination of these processes. In some other illustrative methods, steel or glass carriers, carrier debond processes, or steel or glass carriers and carrier debond processes may be utilized.

Temporary structures formed in methods of packaging microelectronic devices at the panel level may include a plurality of microelectronic dice supported on a printed circuit panel. The printed circuit panel may include vias, and subsets of the vias may be positioned for electrical connection to a respective microelectronic die of the plurality of microelectronic dice. For example, the subset of the vias themselves, or electrically conductive material electrically connected to the vias, may be positioned, sized, shaped, and oriented to align with corresponding electrically conductive elements of microelectronic devices to be supported on the printed circuit panel to facilitate electrical connection thereto.

In some examples, footprints of the microelectronic dice of the plurality of microelectronic dice cover at least some of the vias of the printed circuit panel. Respective vias of the vias of the printed circuit panel may be located outside the footprints of the microelectronic dice of the plurality of microelectronic dice in other examples. At least some of the vias may be, for example, tented and at least partially hollow. An illustrative pitch of the vias of the printed circuit panel may be between 0.65 mm and 1 mm. Dimensions of the printed circuit panel may be, for example, 300 mm by 300 mm, 510 mm by 510 mm, 510 mm by 515 mm, 515 mm by 515 mm, or 600 mm by 600 mm.

The term “printed circuit panel,” as used herein, means and includes a printed circuit board sized, shaped, and configured to support a plurality of microelectronic devices thereon, to be permanently electrically connected to the microelectronic devices, to be singulated into package substrates when forming microelectronic device packages, and having vias for connection to the microelectronic devices. For example, printed circuit panels may be polygonal in shape (e.g., rectangular, square, without limitation) when viewed in a surface view, may define package locations having vias therein, may receive at least one microelectronic device within a respective package location, may have the vias of respective package locations connected to the microelectronic device(s), and may be singulated to form resulting microelectronic device packages.

As used herein, the terms “substantially” and “about” in reference to a given parameter, property, or condition means and includes to a degree that one of ordinary skill in the art would understand that the given parameter, property, or condition is met with a degree of variance, such as within acceptable manufacturing tolerances. For example, a parameter that is substantially or about a specified value may be at least about 90% the specified value, at least about 95% the specified value, at least about 99% the specified value, or even at least about 99.9% the specified value.

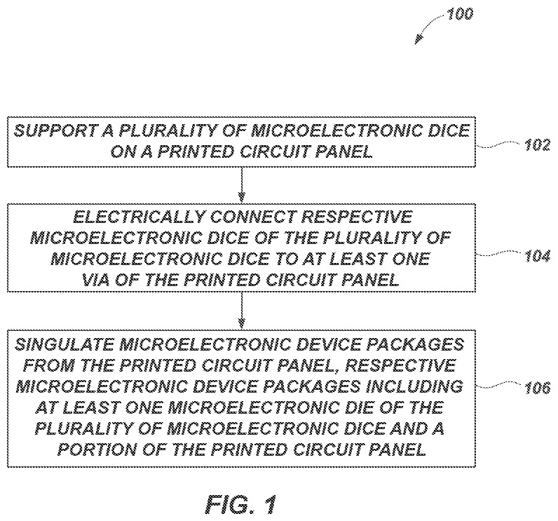

FIG. 1 is a flowchart of a method 100 of packaging microelectronic devices. The method 200 may involve, for example, supporting a plurality of microelectronic dice on a printed circuit panel, as reflected at act 102. Respective microelectronic dice of the plurality of microelectronic dice may be electrically connected to at least one via of the printed circuit panel, as reflected at act 104. Microelectronic device packages may be singulated from the printed circuit panel, respective microelectronic device packages including at least one microelectronic die of the plurality of microelectronic dice and a portion of the printed circuit panel, as indicated at act 106.

Panel-level processing, as set forth in FIG. 1, may conserve costs, as panel-level processing may involve the concurrent and/or sequential performance of repeated processing acts to produce many microelectronic device packages. In contrast to wafer-level processing, panel-level processing may utilize microelectronic dice that have already been singulated from the wafer of material from which those microelectronic dice were formed. Optionally, the microelectronic dice may be subjected to testing, so that further processing and packaging may only be performed on microelectronic dice that are operational according to specifications, sometimes called “known good dice.” The microelectronic dice may be supported on, or otherwise arranged and mutually bound in a molding material to form a panel having dimensions larger than the dimensions of the wafer(s) from which the microelectronic dice were singulated. As a result, a greater number of microelectronic dice may be packaged.

Unlike certain panel-level packaging techniques known to the inventor, which may involve adhering microelectronic dice to a carrier, mutually binding the microelectronic dice in a molding material to form a panel, and subsequently debonding the panel from the carrier, the method 100 of FIG. 1 involves use of a printed circuit panel. Printed circuit panels in accordance with this disclosure may reduce or avoid process steps performed when utilizing other carriers, and may be intended to form permanent connections to the microelectronic dice supported thereon and electrically connected thereto. The printed circuit panels may also be singulated when singulating the microelectronic device packages, such that respective microelectronic device packages may include a portion of the printed circuit panel utilized in the process of its packaging.

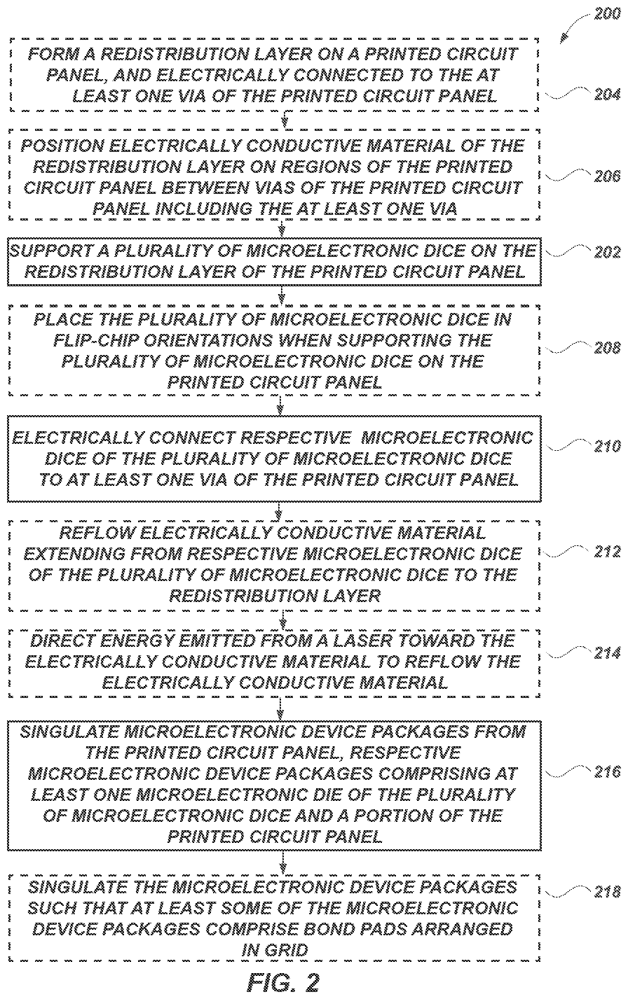

FIG. 2 is a flowchart of another, more specific method 200 of packaging microelectronic devices. As reflected in FIG. 2 the method 200 incorporates the acts performed in connection with the method 100 of FIG. 1, as well as several other optional acts, which are indicated in dashed lines. Similar to the method 100 of FIG. 1, the method 200 of FIG. 2 may involve supporting a plurality of microelectronic dice on a printed circuit panel, as shown at act 202.

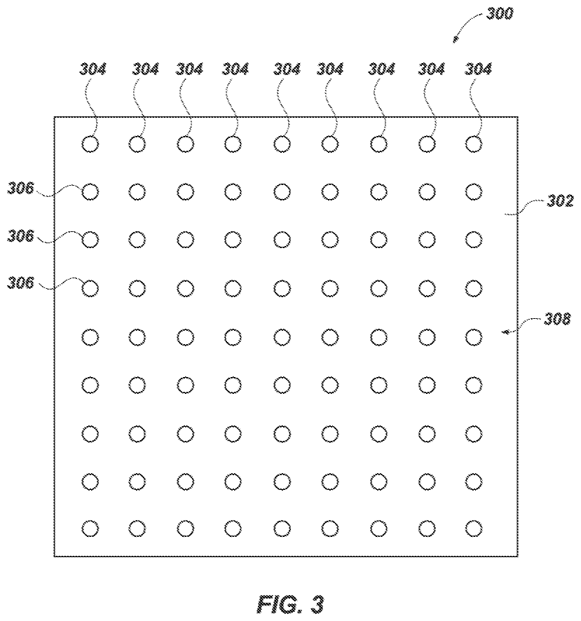

FIG. 3 is a surface view of a printed circuit panel 300, which may be illustrative of one example of a printed circuit panel 300 usable in the method 200 of FIG. 2, such as in the performance of act 202 and any other acts involving a printed circuit panel 300. The printed circuit panel 300 may include materials and be formed utilizing techniques known to those skilled in the art for use with printed circuit boards. For example, the printed circuit panel 300 may include selectively positioned electrically conductive and dielectric materials for making and/or routing electrical connections. In some examples, such as that shown in FIG. 3, the printed circuit panel 300 may include at least one mass (e.g., a layer, without limitation) of dielectric material 302 and a plurality of vias 304 extending through the dielectric material 302. At least some of the vias 304 may be exposed, or may have exposed pads 306, for establishing and routing electrical connections between opposing major surfaces 308 of the printed circuit panel 300. In some examples, printed circuit panels 300 in accordance with this disclosure may lack traces for routing electrical connections. The printed circuit panel 300, and the vias 304 thereof, may define a plurality of package locations, respective package locations for receiving one or more microelectronic dice and for forming a respective microelectronic device package.

In other examples, printed circuit panels in accordance with this disclosure may include traces for routing electrical connections. More specifically, the printed circuit panels may include, for example, traces of electrically conductive material (e.g., etched foil of copper, gold, aluminum, alloys including one or more of such materials, without limitation) on one or more major surfaces of the printed circuit panels and/or laminated between layers of the dielectric material. In some examples where the printed circuit panels include traces, the printed circuit panels may lack through vias that would extend entirely through the thickness of the printed circuit panels, and may have partial vias which connect from a major surface 308 to a trace of electrically conductive material on an intermediate layer of the dielectric material, and/or pads in connection with the traces. In other examples, the vias 304 of the printed circuit panels may be through vias.

The major surface 308 of the printed circuit panel 300 may have a larger surface area than a surface area of a wafer from which microelectronic dice to be supported on the printed circuit panel 300 may be singulated. For example, a surface area of the major surface 308 of the printed circuit panel 300 may be between about 90,000 mm² and about 360,000 mm². More specifically, the surface area of the major surface 308 of the printed circuit panel 300 may be between about 260,100 mm² and about 360,000 mm². As a specific, nonlimiting example, the surface area of the major surface 308 of the printed circuit panel 300 may be between about 262,650 mm² and about 360,000 mm² (e.g., about 265,225 mm², without limitation).

When viewed in a surface view, as in FIG. 3, a periphery of the major surface 308 of the printed circuit panel 300 may have a different shape than a shape of a wafer from which microelectronic dice to be supported on the printed circuit panel 300 may be singulated. For example, wafers from which microelectronic dice are diced may generally have a circular shape when viewed in a surface view, whereas the printed circuit panel 300 may have a polygonal shape having at least four sides and four internal angles when viewed in a surface view. More specifically, the periphery of the major surface 308 of the printed circuit panel 300 may form a rectangle, a square, or another polygon when viewed in a surface view.

In examples where the printed circuit panel 300 is rectangular or square when viewed in a surface view, dimensions of the printed circuit panel 300 may be, for example, between about 300 mm by about 300 mm and about 600 mm by about 600 mm. More specifically, dimensions of the printed circuit panel 300 may be, for example, between about 510 mm by about 510 mm and about 515 mm by about 515 mm. As a specific, nonlimiting example, dimensions of the printed circuit panel 300 may be about 510 mm by about 515 mm.

In some examples, such as that shown in FIG. 3 the vias 304 may be arranged in an array or other repeating pattern, distributed across the major surface 308 of the printed circuit panel 300. For example, the vias 304 may form a grid, including rows and columns of vias 304 arranged in repeating patterns. In some such examples, the printed circuit panel 300 may conform to a standardized spacing and distribution of the vias 304, forming a pattern that may be usable with a wide variety of microelectronic dice to be packaged and requiring little to no customized layout and signal routing. In other examples, the vias may be positioned in a customized layout to facilitate particular microelectronic dice to be packaged.

A pitch of the vias 304 of the printed circuit panel 300, as measured by calculating an average of the shortest distances between centers of adjacent vias 304 in respective rows and respective columns, may be, for example, between about 0.65 mm and about 1 mm. More specifically, the pitch of the vias 304 may be, for example, between about 0.7 mm and about 0.95 mm. As a specific, nonlimiting example, the pitch of the vias 304 may be between about 0.75 mm and about 0.9 mm (e.g., about 0.8 mm, about 0.85 mm, without limitation). Thus, the number and size of the vias 304 in relation to the size of the printed circuit panel 300 depicted in FIG. 3 may not be to scale.

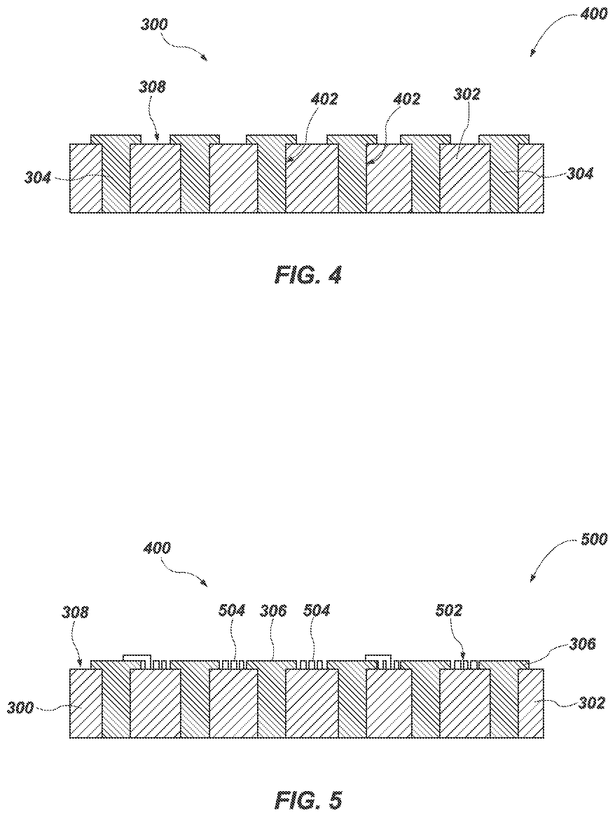

FIG. 4 is a cross-sectional side view of a portion of the printed circuit panel 300 of FIG. 3. The portion depicted in FIG. 4 may correspond to a package location 400 of the printed circuit panel 300, and the printed circuit panel 300 may include a plurality of such package locations 400. For example, the package locations 400 may be distributed in a grid or other array on the major surface 308 of the printed circuit panel 300, enabling the concurrent packaging of multiple microelectronic device packages, with respective microelectronic device packages in their own package location 400.

In some examples, the printed circuit panel 300 may include solid vias 304, having a solid mass of electrically conductive material located within bores 402 extending partially or completely through the printed circuit panel 300. As shown in FIG. 4, there may be a single mass (e.g., layer, without limitation) of dielectric material 302 having a plurality of bores 402 extending entirely through the dielectric material 302 of the printed circuit panel 300. In other examples, the vias may be hollow, having electrically conductive material lining surfaces of the dielectric material 302 defining the bores 402, and volumes within the electrically conductive material that may be filled with environmental fluid (e.g., air, an inert gas, without limitation) or may be occupied by a filler material (e.g., flux, without limitation). In some such examples, the hollow vias may be tented, such as, for example, by positioning a masking material at least temporarily over the hollow portion of the vias, blocking fluid passage through the hollow portion of the vias, which may facilitate use of pressure in certain packaging and handling techniques (e.g., vacuum handling, without limitation).

Returning to FIG. 2, the method 200 may involve forming a redistribution layer on the printed circuit panel, the redistribution layer electrically connected to the at least one via of the printed circuit panel, before any microelectronic dice are supported on the printed circuit panel, as indicated at act 204. Forming the redistribution layer may involve positioning electrically conductive material of the redistribution layer on regions of the printed circuit panel between vias of the printed circuit panel including the at least one via, as indicated at act 206. For example, a masking material (e.g., a photoresist material, without limitation) may be positioned on the major surface of the printed circuit panel, portions of the masking material may be selectively removed (e.g., by overlaying a mask and exposing the masking material to radiative energy, without limitation), electrically conductive material may be positioned on the major surface in regions exposed by selectively removing the portions of the masking material (e.g., by a plating process, without limitation), and the remaining masking material may be removed (e.g., by exposure to a solvent, without limitation).

FIG. 5 is a cross-sectional side view of a temporary structure 500 in a first stage of either of the method 100 of FIG. 1 or the method 200 of FIG. 2. In particular, the temporary structure 500 of FIG. 5 depicts the package location 400 of the printed circuit panel 300 following performance of act 204 and act 206 of the method 200 of FIG. 2. The temporary structure 500 may include a redistribution layer 502 positioned on the major surface 308 of the printed circuit panel 300. The redistribution layer 502 may include traces 504 of, or including, an electrically conductive material supported on the major surface 308 of the printed circuit panel 300. The traces 504 of the redistribution layer 502 may be located primarily in locations between and among the vias 304. For example, the traces 504 may be primarily supported on the dielectric material 302 of the printed circuit panel 300, and may be electrically connected to the vias 304. In examples where the vias 304 include pads 306, portions of the electrically conductive material of the redistribution layer 502 may extend between the pads 306 (e.g., from surfaces of the pads 306 distal from the dielectric material 302 of the printed circuit panel 300 to the major surface 308 of the printed circuit panel 300, without limitation) and the traces 504 may be positioned to electrically connect the pads 306 to one or more corresponding microelectronic devices.

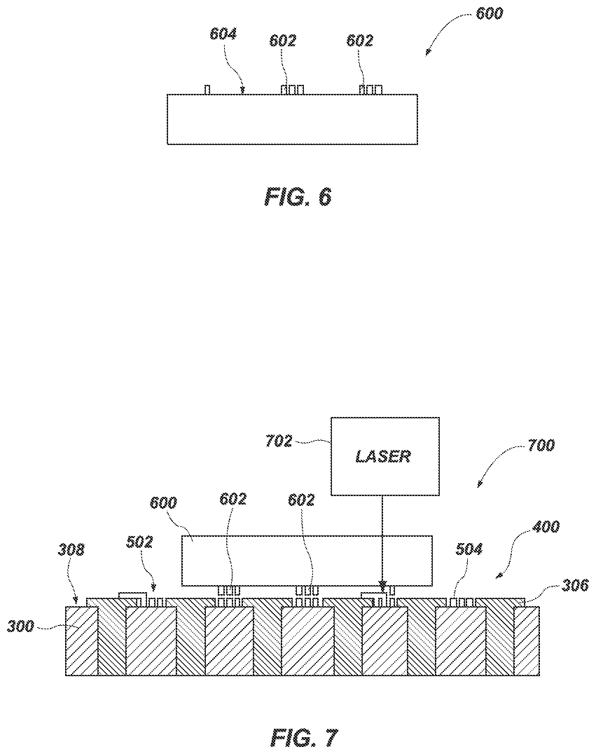

FIG. 6 is a cross-sectional side view of a microelectronic die 600. The microelectronic die 600 may bear integrated circuitry supported on and/or embedded within a material of the microelectronic die 600. For example, the microelectronic die 600 may include a semiconductor material, which may be doped to form at least some of the integrated circuitry of the microelectronic die 600. The microelectronic die 600 may include electrically conductive elements 602 in electrical connection with the integrated circuitry, supported on a major surface 604 of the microelectronic die 600, and positioned to connect the integrated circuitry of the microelectronic die 600 to higher level packaging. For example, the electrically conductive elements 602 may include pillars, posts, columns, bumps, balls, or other masses of electrically conductive material (e.g., copper, gold, aluminum, tin, silver, alloys including the foregoing, solder, without limitation), at least a portion of which may be reflowable. As specific, nonlimiting examples, the electrically conductive elements 602 may include copper pillars topped and/or tipped with a solder material, which may be referred to in the art as a “copper pillar bump,” or may include solder bumps.

Returning to FIG. 2, the method 200 may involve placing the plurality of microelectronic dice in flip-chip orientations when supporting the plurality of microelectronic dice on the printed circuit panel, as indicated at act 202 and act 208. For example, a pick-and-place operation may be performed to retrieve microelectronic dice 600 (e.g., one at a time, or one at a time per manipulating mechanism of a pick-and-place machine, without limitation), orient the microelectronic dice 600 such that electrically conductive elements of the microelectronic dice 600 face toward the printed circuit panel 300 and the redistribution layer 502 supported thereon, align the electrically conductive elements 602 with portions of the redistribution layer 502 positioned for electrical connection to the microelectronic dice 600, and position at least one microelectronic die 600 in respective package locations on the printed circuit panel 300.

FIG. 7 is a cross-sectional side view of another temporary structure 700 in a second stage of the method 100 of FIG. 1 or the method 200 of FIG. 2. The temporary structure 700 of FIG. 7 depicts the package location 400 of the printed circuit panel 300 following performance of at least act 202 and act 208 of the method 200 of FIG. 2. The temporary structure 700 may include the microelectronic die 600 supported on the same side of the printed circuit panel 300 as the redistribution layer 502. More specifically, the electrically conductive elements 602 of the microelectronic die 600 may be, for example, on a side of the microelectronic die 600 proximate to the printed circuit panel 300, and the electrically conductive elements 602 may be in contact with, and supported on, traces 504 of the redistribution layer 502, pads 306 of the vias 304, or other electrically conductive structures of the redistribution layer 502, the vias 304, or both.

In some examples where the electrically conductive elements 602 of the microelectronic die 600 include a flowable material (e.g., solder, without limitation), electrically connecting the microelectronic die 600 to at least one via 304 of the printed circuit panel 300, as indicated at act 210, may involve reflowing electrically conductive material extending from the microelectronic die 600 to the redistribution layer 502. As panel-level processing may be contemplated, the process of bringing the flowable material into contact with, or at least proximate to, the redistribution layer 502 and/or the vias 304, reflowing the flowable material, and causing the flowable material to electrically connect the electrically conductive elements 602 of the microelectronic die 600 may be performed for a plurality of such microelectronic dice 600, as indicated at act 212 in FIG. 2.

Reflowing the flowable material may generally involve exposing the flowable material of the electrically conductive elements 602 to one or more heat sources. As one example, energy emitted from a laser 702 may be directed toward the flowable, electrically conductive material of the electrically conductive elements 602, as indicated at act 214 in FIG. 2. To reduce the risk of damaging integrated circuitry of the microelectronic die 600, the energy emitted from the laser 702 may be of an intensity, and the duration of exposure to the energy emitted from the laser 702 may be sufficiently brief, such that temperatures within the material of the microelectronic die 600 may remain below a specified threshold. The energy emitted by the laser 702 may be directable toward various regions of the printed circuit panel 300, enabling the laser 702 to reflow respective quantities of the flowable, electrically conductive material of the electrically conductive elements 602. For example, the laser 702 may be mounted on a movable gantry, and may follow a rasterization pattern when reflowing the flowable electrically conductive material of the electrically conductive elements 602. In other examples of methods of exposing the flowable electrically conductive material of the electrically conductive elements 602 to one or more heat sources, the printed circuit panel 300, and the associated electrically conductive elements 602, may be placed in an oven. In other examples of methods for reflowing flowable electrically conductive material, the flowable electrically conductive material of the electrically conductive elements 602 may be exposed to vibratory energy, such that friction between the electrically conductive elements 602 and any contacting material may heat the electrically conductive elements 602 to reflow the flowable electrically conductive material of the electrically conductive elements 602.

In examples where a plurality of microelectronic dice 600 are supported on the printed circuit panel 300, subsets of the vias 304 may be positioned for electrical connection to a respective microelectronic die 600 of the plurality of microelectronic dice 600. For example, respective package locations 400 of the printed circuit panel 300 may include some vias 304 within the footprint of the package location 400, at least one via 304 being positioned for electrical connection to one or more microelectronic dice 600 to form a microelectronic device package to be singulated from the printed circuit panel 300. Stated another way, the package locations 400 may divide and define the subsets of vias 304.

In some examples, footprints of the microelectronic dice 600 of the plurality of microelectronic dice 600 may cover at least some of the vias 304 of the printed circuit panel 300. As one such example, the pitch of the vias 304, as measured and defined by a shortest distance between centers of adjacent vias 304 in a direction at least substantially parallel to the major surface 308 of the printed circuit panel 300, may be smaller than the footprint of a microelectronic die 600, and the vias 304 may be distributed in such a manner as to cause at least some of the vias 304 to underlie an associated microelectronic die 600. More specifically, the vias 304 may be distributed in a pattern resembling nodes of a grid, and placing the microelectronic die 600 over the major surface 308 of the printed circuit panel 300 may cause the microelectronic die 600 to cover at least some of the vias 304 within the package location 400.

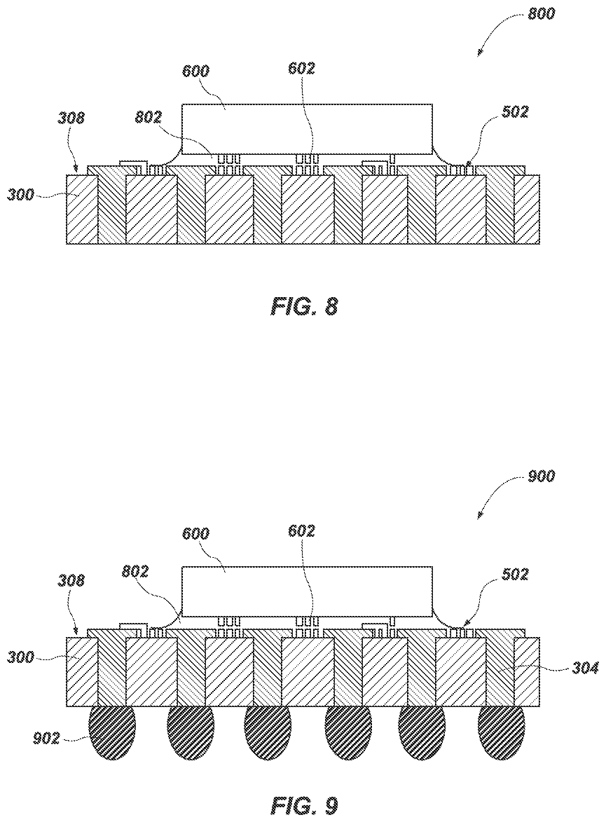

FIG. 8 is a cross-sectional side view of another temporary structure 800 in a third stage of the method 100 of FIG. 1 or the method 200 of FIG. 2. In some examples, such as that shown in FIG. 8, an underfill material 802 may be placed between the microelectronic die 600 and the printed circuit panel 300. For example, the underfill material 802 may initially be in a flowable state, and may be dispensed or otherwise positioned to flow under the microelectronic die 600 and around portions of the major surface 308 of the printed circuit panel 300, of the redistribution layer 502, and of the electrically conductive elements 602. The underfill material 802 may include a curable polymer material which may subsequently be cured. In some examples, heat from curing the underfill material 802 may be sufficient to reflow the flowable, electrically conductive material of the electrically conductive elements 602. The underfill material 802 may include, for example, any underfill material 802 known in the art. As with other acts, the act of positioning underfill material 802 between the microelectronic die 600 and the printed circuit panel 300 may be repeated for at least some, and up to each, microelectronic die 600 supported on the printed circuit panel 300. In other examples, no underfill material 802 may be positioned between one or more of the microelectronic dice 600 and the printed circuit panel 300.

Returning again to FIG. 2, the method 200 may involve singulating microelectronic device packages from the printed circuit panel, as indicated at act 216. Respective microelectronic device packages may include at least one microelectronic die of the plurality of microelectronic dice and a portion of the printed circuit panel, as further indicated at act 216. More specifically, the method 200 may involve, for example, singulating the microelectronic device packages such that at least some of the microelectronic device packages comprise bond pads arranged in a grid, as indicated at act 218. As a specific, nonlimiting example, a saw or saws may be utilized to cut through the printed circuit panel along streets between selected rows and columns of the grid of vias, separating individual package locations 400 from one another to form microelectronic device packages.

FIG. 9 is a cross-sectional side view of a microelectronic device package 900. The microelectronic device package 900 of FIG. 9 depicts the package location 400 of the printed circuit panel following performance of at least act 216 and act 218 of the method 200 of FIG. 2. The microelectronic device package 900 may include, for example, at least one microelectronic die 600 supported on, and electrically connected to, a package location 400 defined by a portion of the printed circuit panel 300. The package location 400 may include vias 304, a redistribution layer 502 electrically connected to the vias 304, and electrically conductive elements 602 electrically connecting the microelectronic die 600 to the redistribution layer 502. An underfill material 802 may be interposed between the microelectronic die 600 and the portion of the printed circuit panel 300. In some examples, the microelectronic device package 900 may include an encapsulant material encapsulating respective microelectronic dice 600 and at least a portion of the redistribution layer 502 and the major surface 308 of the portion of the printed circuit panel 300 located outside the footprint of the relevant microelectronic die 600. In some examples, the microelectronic device package 900 may include a thermal management structure, such as, for example, a heat spreader, a heat sink, or another thermal management structure known in the art, disposed on the microelectronic device package 900 (e.g., in contact with the microelectronic die 600, without limitation).

The microelectronic device package 900 may include conductive elements 902 positioned to connect the microelectronic device package 900 to higher-level packaging. For example, the conductive elements 902 of the microelectronic device package 900 may include masses of electrically conductive material electrically connected, and affixed, to portions of the vias 304 on a side of the portion of the printed circuit panel 300 facing away from the microelectronic die 600. More specifically, the conductive elements 902 may include bumps, balls, pillars, columns, or other known shapes and configurations including electrically conductive material (e.g., solder, without limitation).

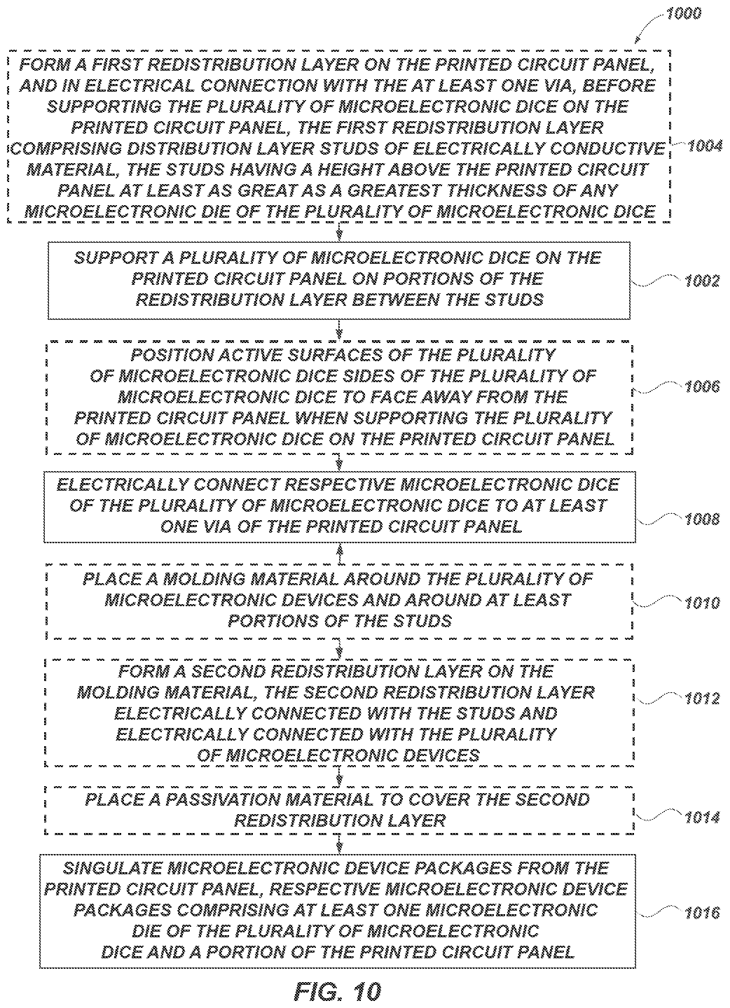

FIG. 10, similar to FIG. 2, is a flowchart of another, more specific method 1000 of packaging microelectronic devices. As reflected in FIG. 10 the method 1000 incorporates the acts performed in connection with the method 100 of FIG. 1, as well as several other optional acts, which are indicated in dashed lines. Similar to the method 100 of FIG. 1, the method 1000 of FIG. 10 may involve supporting a plurality of microelectronic dice on a printed circuit panel, as shown at act 1002. The method 1000 may further involve forming a first redistribution layer on the printed circuit panel, and in electrical connection with the vias, before supporting the plurality of microelectronic dice on the printed circuit panel, as indicated at act 1004. The first redistribution layer may include distribution layer studs of electrically conductive material, the studs having a height above the printed circuit panel at least as great as a greatest thickness of any microelectronic die of the plurality of microelectronic dice, as further indicated at act 1004. Forming the redistribution layer may involve performing any of the actions described previously in connection with act 206, and further involving building up portions of the electrically conductive material to form the studs or positioning preformed studs including electrically conductive material on portions of the redistribution layer.

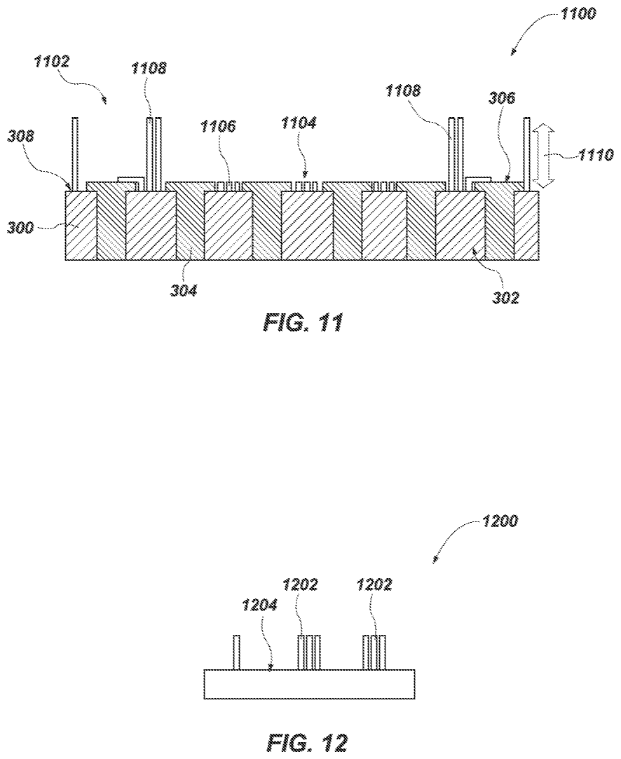

FIG. 11 is a cross-sectional side view of a temporary structure 1100 in a first stage of the method 100 of FIG. 1 or the method 1000 of FIG. 10. More specifically, the temporary structure 1100 of FIG. 11 depicts a package location 1102 of the printed circuit panel 300 following performance of act 1004 of the method 1000 of FIG. 10. The temporary structure 1100 may include a first redistribution layer 1104 positioned on the major surface 308 of the printed circuit panel 300. The first redistribution layer 1104 may include traces 1106 of, or including, an electrically conductive material supported on the major surface 308 of the printed circuit panel 300. The first redistribution layer 1104 may further include distribution layer studs 1108 including electrically conductive material. The distribution layer studs 1108 may have a height 1110 above the printed circuit panel 300, as measured in a direction at least substantially perpendicular to the major surface 308 of the printed circuit panel 300, at least as great as a greatest thickness of any microelectronic die of the plurality of microelectronic dice. The distribution layer studs 1108 may be supported on, and extend from, the traces 1106.

The traces 1106 and distribution layer studs 1108 of the first redistribution layer 1104 may be located primarily in locations between and among the vias 304. For example, the traces 1106 may be primarily supported on the dielectric material 302 of the printed circuit panel 300, and may be electrically connected to the vias 304. In examples where the vias 304 include pads 306, portions of the electrically conductive material of the first redistribution layer 1104 may extend to the pads 306 (e.g., on surfaces of the pads 306 distal from the dielectric material 302 of the printed circuit panel 300, without limitation) to electrically connect the traces 1106 and the distribution layer studs 1108 to the pads 306, and thereby to the vias 304.

FIG. 12 is a cross-sectional side view of another microelectronic die 1200. The microelectronic die 1200 may bear integrated circuitry supported on and/or embedded within a material of the microelectronic die 1200, as described previously in connection with the microelectronic die 600 of FIG. 6. The microelectronic die 1200 may include microelectronic die studs 1202 in electrical connection with the integrated circuitry, supported on a major surface 1204 of the microelectronic die 1200, and positioned to connect the integrated circuitry of the microelectronic die 1200 to higher level packaging. For example, the microelectronic die studs 1202 may be taller, as measured in a direction at least substantially perpendicular to the major surface 1204, than they are wide, as measured in a direction at least substantially parallel to the major surface 1204. In some examples, the microelectronic die studs 1202 may be at least substantially free of flowable, electrically conductive material, the electrically conductive material of the microelectronic die studs 1202 being configured not to reflow following their positioning on the major surface 1204 of the microelectronic die 1200.

Returning to FIG. 10, the method 1000 may involve positioning active surfaces of the plurality of microelectronic dice to face away from the printed circuit panel when supporting the plurality of microelectronic dice on the printed circuit panel, as indicated at act 1006. The positioning may be accomplished utilizing, for example, any of the techniques discussed previously in connection with FIG. 2.

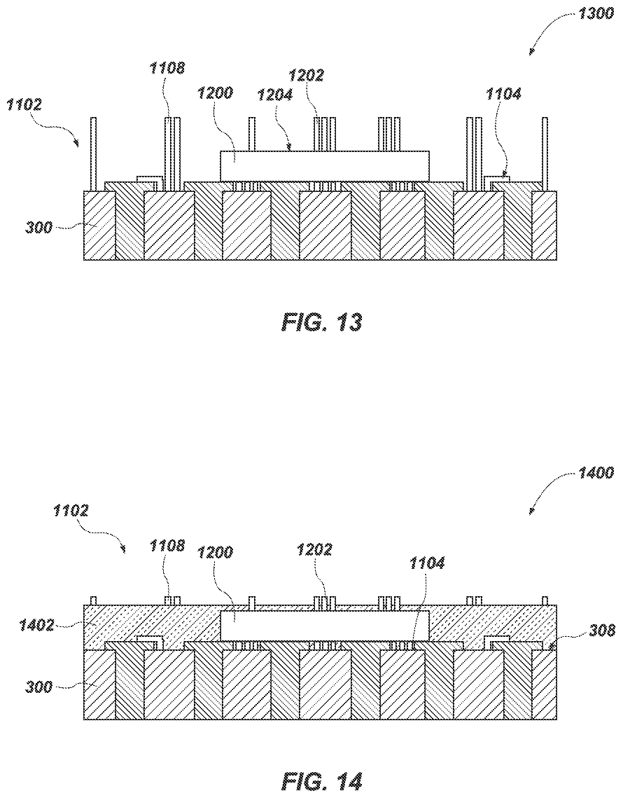

FIG. 13 is a cross-sectional side view of another temporary structure 1300 in a second stage of the method 100 of FIG. 1 or the method 1000 of FIG. 10. The temporary structure 1300 of FIG. 13 depicts the package location 1102 of the printed circuit panel 300 following performance of at least act 1006 of the method 1000 of FIG. 10. The temporary structure 1300 may include the microelectronic die 1200 supported on the same side of the printed circuit panel 300 as the first redistribution layer 1104. The microelectronic die studs 1202 of the microelectronic die 1200 may be located on a side of the microelectronic die 1200 facing away from the printed circuit panel 300. The distribution layer studs 1108 and the microelectronic die studs 1202 may terminate at least substantially at the same height above the major surface 308 of the printed circuit panel 300, as measured in a direction at least substantially perpendicular to the major surface 308.

The microelectronic die 1200 may be supported on the printed circuit panel 300 on portions of the first redistribution layer 1104 between the distribution layer studs 1108. For example, the distribution layer studs 1108 may be located outside the footprint of the microelectronic die 1200, may be located proximate to one or more lateral sides of the microelectronic die 1200, and may extend to heights above the major surface 308 of the printed circuit panel 300 higher than the major surface 1204 of the microelectronic die 1200. The distribution layer studs 1108 may be located adjacent to the microelectronic die 1200 on two opposite lateral sides, on two adjacent lateral sides, on any three sides, on all four sides (in examples where the microelectronic die 1200 has an at least substantially rectangular shape when viewed in a surface view), or on respective sides regardless of number (in examples where the microelectronic die 1200 has fewer than or more than four sides).

Returning to FIG. 10, the method 1000 may involve, as part of the process of electrically connecting respective microelectronic dice of the plurality of microelectronic dice to at least one via of the printed circuit panel as indicated at act 1008, placing a molding material around the plurality of microelectronic devices and around at least portions of the studs, as indicated at act 1010. For example, the molding material may initially be in a flowable state, and may dispensed or otherwise positioned under, around, and over the microelectronic die 1200 and covering portions of the major surface of the printed circuit panel and of the first redistribution layer. The molding material may further be positioned at least laterally around portions of, and in some examples, completely covering, the distribution layer studs and the microelectronic die studs. The molding material may include a curable polymer material which may subsequently be cured.

FIG. 14 is a cross-sectional side view of another temporary structure 1400 in a third stage of the method 100 of FIG. 1 or the method 1000 of FIG. 10. The temporary structure 1400 of FIG. 14 depicts the package location 1102 of the printed circuit panel 300 following performance of at least act 1010 of the method 1000 of FIG. 10. The temporary structure 1400 may include the molding material 1402, which may mutually bind respective microelectronic dice 1200, distribution layer studs 1108, and microelectronic die studs 1202 within the molding material 1402. More specifically, the molding material 1402 may contact, and at least partially cover, the major surface 308 of the printed circuit panel 300, the first redistribution layer 1104, the microelectronic die 1200, the distribution layer studs 1108, and the microelectronic die studs 1202, in respective package locations 1102. In some examples, portions of the distribution layer studs 1108 and the microelectronic die studs 1202 may remain exposed above the molding material 1402. In other examples, the molding material 1402 may completely cover the distribution layer studs 1108 and the microelectronic die studs 1202, and a portion of the molding material 1402 may be removed to expose the distribution layer studs 1108 and the microelectronic die studs 1202 (e.g., by backgrinding, without limitation). Regardless, a planarization process may be performed to render the molding material 1402, the distribution layer studs 1108, and the microelectronic die studs 1202 at least substantially flush with one another.

Returning to FIG. 10, the method 1000 may further involve, as part of the process of electrically connecting respective microelectronic dice of the plurality of microelectronic dice to at least one via of the printed circuit panel, forming a second redistribution layer on the molding material, in electrical connection with the studs, and in electrical connection with the plurality of microelectronic devices, as indicated at act 1012. For example, the second redistribution layer may be formed utilizing any of the techniques and structures discussed previously in connection with FIG. 5 and FIG. 11, as applied to the molding material and the studs.

FIG. 15 is a cross-sectional side view of another temporary structure 1500 in a fourth stage of the method 100 of FIG. 1 or the method 1000 of FIG. 10. More specifically, the temporary structure 1500 of FIG. 15 depicts a package location 1102 of the printed circuit panel 300 following performance of act 1012 of the method 1000 of FIG. 10. The temporary structure 1500 may include a second redistribution layer 1502 positioned on the molding material 1402, on a side of the molding material 1402 facing away from the printed circuit panel 300. The second redistribution layer 1502 may include traces 1504 of, or including, an electrically conductive material supported on the molding material 1402. The traces 1504 of the second redistribution layer 1502 may be electrically connected to the distribution layer studs 1108 of the first redistribution layer 1104 and the microelectronic die studs 1202 of the microelectronic die 1200. Thus, the microelectronic die 1200 may be electrically connected to the vias 304 by the microelectronic die studs 1202 extending from the microelectronic die 1200, the second redistribution layer 1502 connected to the microelectronic die studs 1202, the distribution layer studs 1108 connected to the second redistribution layer 1502, and the first redistribution layer 1104 connected to the distribution layer studs 1108 and the vias 304.

Returning to FIG. 10, the method 1000 may further involve placing a passivation material to cover the second redistribution layer, as indicated at act 1014. For example, the second redistribution layer may be covered by a passivation material including another quantity of molding material, which may be flowed and cured, as discussed previously in connection with FIG. 14.

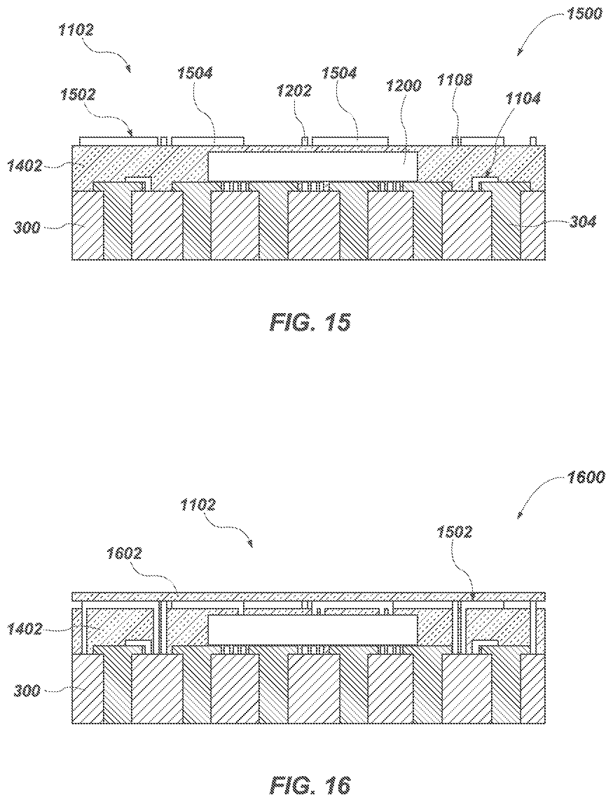

FIG. 16 is a cross-sectional side view of another temporary structure 1600 in a fifth stage of the method 100 of FIG. 1 or the method 1000 of FIG. 10. More specifically, the temporary structure 1500 of FIG. 15 depicts a package location 1102 of the printed circuit panel 300 following performance of act 1014 of the method 1000 of FIG. 10. The temporary structure 1500 may include a passivation material 1602 positioned to protect the second redistribution layer 1502. For example, the passivation material 1602 may cover the second redistribution layer 1502, and portions of the molding material 1402, on sides of the second redistribution layer 1502 and the molding material 1402 facing away from the printed circuit panel 300. The passivation material 1602 may include, for example, a dielectric material. More specifically, the passivation material 1602 may include, for example, a curable polymer material.

Again returning to FIG. 10, the method 1000 may involve singulating microelectronic device packages from the printed circuit panel, as indicated at act 1016. Respective microelectronic device packages may include at least one microelectronic die of the plurality of microelectronic dice and a portion of the printed circuit panel, as also indicated at act 1016. For example, the act of singulation, and any further actions taken in furtherance of completing the microelectronic device packages or configuring them for connection to higher-level packaging, may be accomplished by performing any of the actions described previously in connection with FIG. 2 and FIG. 9.

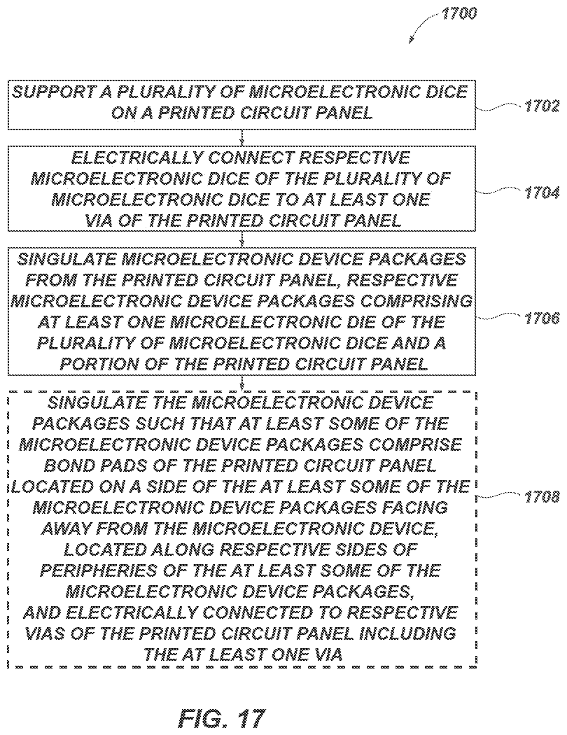

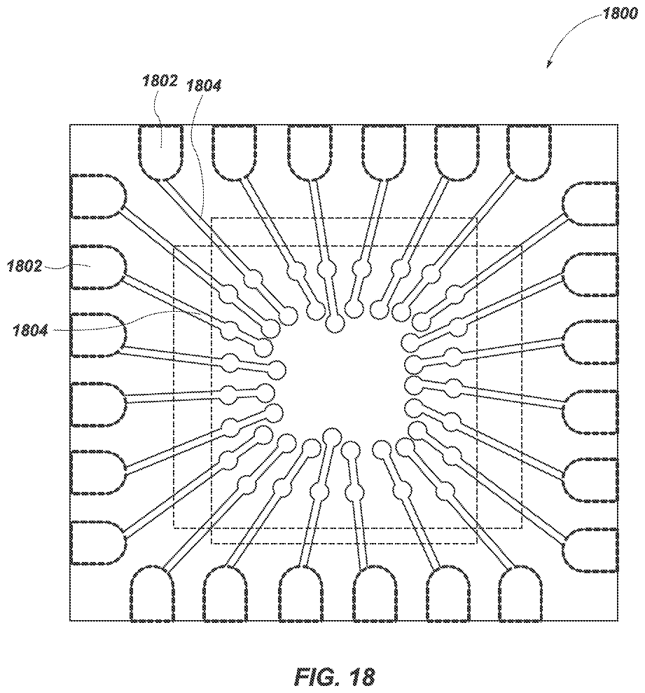

FIG. 17 is a flowchart of another method 1700 of packaging microelectronic devices. As reflected in FIG. 17 the method 1700 may incorporate the acts performed in connection with the method 100 of FIG. 1, as well as another optional act, which is indicated in dashed lines. The method 1700 may involve, for example, supporting a plurality of microelectronic dice on a printed circuit panel, as reflected at act 1702. Respective microelectronic dice of the plurality of microelectronic dice may be electrically connected to at least one via of the printed circuit panel, as reflected at act 1704. Microelectronic device packages may be singulated from the printed circuit panel, respective microelectronic device packages including at least one microelectronic die of the plurality of microelectronic dice and a portion of the printed circuit panel, as indicated at act 1706. As further indicated at act 1708, the microelectronic device packages may be singulated such that at least some of the microelectronic device packages comprise bond pads located on a side of the at least some of the microelectronic device packages facing away from the microelectronic device, located along respective sides of peripheries of the at least some of the microelectronic device packages, and electrically connected to respective vias of the printed circuit panel including the at least one via.

FIG. 18 is a surface view of another microelectronic device package 1800. The dashed lines in FIG. 18 depict illustrative outlines of microelectronic dice, including size, shape, and orientation, that may be included in the microelectronic device package 1800 of FIG. 18. The microelectronic device package 1800 may include bond pads 1802 located along respective sides of a periphery of the microelectronic device package 1800. For example, the bond pads 1802 may be distributed around a perimeter of the microelectronic device package 1800, and may be positioned to facilitate connection to higher-level packaging. Respective ones of bond pads 1802 may be electrically connected to internal components of the microelectronic device package 1800, such as one or more microelectronic dice, utilizing respective ones of traces 1804. The traces 1804 in FIG. 18 are depicted in solid lines for the sake of simplicity, and the traces 1804 may be exposed at an outer surface of the microelectronic device package 1800, or may be located within the microelectronic device package 1800 to reduce the risk of damage to the traces 1804. Generally, the configuration depicted in FIG. 18 may be similar to what is referred to in the art as a “quad-flat, no lead” (QFN) package, as the microelectronic device package 1800 includes bond pads 1802 distributed around all four sides, exposed for connection, in at least substantially the same plane as one another, and lacking leads in the form of depending fingers for insertion into a receiving socket, as one might find on a lead frame.

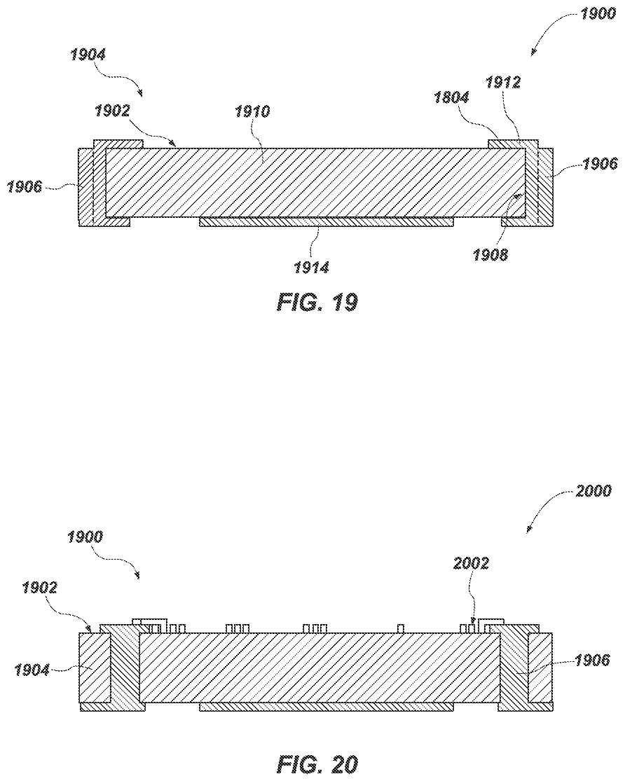

FIG. 19 is a cross-sectional view of a portion of another printed circuit panel 1904. Similar to the portion depicted in FIG. 4, the portion depicted in FIG. 19 may correspond to a package location 1900 of the printed circuit panel 1904, and the printed circuit panel 1904 may include a plurality of such package locations 1900. For example, the package locations 1900 may be distributed in a grid or other array on a major surface 1902 of the printed circuit panel 1904, enabling the concurrent packaging of multiple microelectronic device packages, respective microelectronic device packages in their own package location 1900.

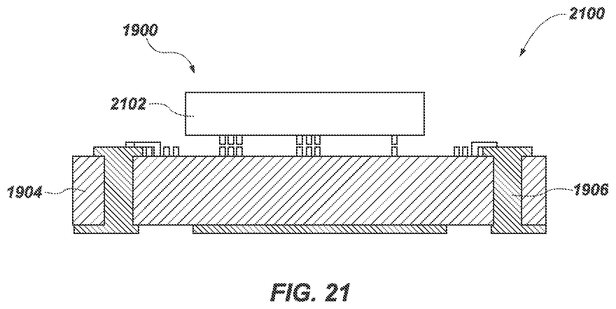

The vias 1906 of respective package locations 1900 may be located proximate to the periphery of the package location 1900, and distal from the geometric center of the package location 1900. For example, the vias 1906 of the printed circuit panel 1904 may be distributed in repeating patterns of peripherally distributed perimeters around respective package locations 1900, with streets between the package locations 1900. Traces 1804 may extend from the vias 1906 closer to the geometric center of the package location 1900 for electrical connection to one or more microelectronic dice. In some examples, at least one package location 1900, and optionally each package location 1900, may include a thermal pad 1914 located on a side of the printed circuit panel 1904 opposite the major surface 1902 on which a redistribution layer 2002 (see FIG. 20) may be formed. The thermal pad 1914 may include, for example, a mass of thermally conductive material (e.g., a metal material, a metal alloy material) adhered to or otherwise supported from the printed circuit panel 1904 in the associated package location 1900. The thermal pad 1914 may facilitate dissipation (e.g., spreading) of heat generated by a microelectronic device package to be formed from the package location 1900.

As discussed previously in connection with FIG. 3, the printed circuit panel 1904 of FIG. 19 may include materials and be formed utilizing techniques known to those skilled in the art for use with printed circuit boards. For example, the printed circuit panel 1904 may include any of the materials, any of the configurations, and may be formed utilizing any of the techniques discussed previously in connection with FIG. 3. In some examples, the printed circuit panel 1904 may include vias 1906 which may be tented and at least partially hollow. For example, rather than a solid mass of electrically conductive material occupying all space defined by the sidewalls 1908 of the dielectric material 1910 defining the vias 1906, electrically conductive material of the at least partially hollow vias 1906 may be positioned primarily on the sidewalls 1908 and may define a column (e.g., an at least substantially cylindrical, without limitation) occupied by environmental fluid (e.g., air, without limitation).

The vias 1906 may be tented, in that the vias 1906 may include a tenting material 1912 at least partially occluding the at least partially hollow vias 1906. Such occlusion may inhibit or prevent environmental fluid (e.g., air, without limitation) from passing through the at least partially hollow vias 1906, which may facilitate handling utilizing pressure-based manipulators (e.g., vacuum chucks, without limitation). The tenting material 1912 may subsequently be removed, which may enable connection to higher-level packaging to be accomplished utilizing through-hole soldering techniques, and the accompanying ability to visually inspect and verify the quality of any electrical connection made thereby. The at least partially hollow vias 1906, and the associated tenting material 1912, may be formed utilizing any of the techniques and materials known in the art for such structures. In some examples, singulation of individual package locations 1900 of the printed circuit panel 1904 from one another may involve cutting through the previously tented, at least partially hollow vias 1906, leaving vias 1906 forming an incomplete, generally circular shape (e.g., half circles), sometimes called “castellations.”

FIG. 20 is a cross-sectional side view of a temporary structure 2000 in a first stage of the method 100 of FIG. 1 or the method 1700 of FIG. 17. More specifically, the temporary structure 2000 of FIG. 20 depicts a package location 1900 of the printed circuit panel 1904 in preparation for performance of act 1702 of the method 1700 of FIG. 17. The temporary structure 2000 may include a redistribution layer 2002 positioned on the major surface 1902 of the printed circuit panel 1904. The redistribution layer 2002 may include any of the structures and materials, and may be formed utilizing any of the techniques discussed previously in connection with FIG. 5 and FIG. 11. For example, the redistribution layer 2002 may include traces electrically connected to the vias 1906.

Returning to FIG. 17, the method 1700 may involve supporting a plurality of microelectronic dice on a printed circuit panel, as indicated at act 1702. The method 1700 may further involve electrically connecting respective microelectronic dice of the plurality of microelectronic dice to at least one via of the printed circuit panel, as indicated at act 1704. Such tasks may be accomplished by performing any of the actions described previously in connection with FIG. 7 and FIG. 13 through FIG. 15.

FIG. 21 is a cross-sectional side view of another temporary structure 2100 in a second stage of the method 100 of FIG. 1 or the method 1700 of FIG. 17. In particular, the temporary structure 2100 of FIG. 21 depicts a package location 1900 of the printed circuit panel 1904 following performance of act 1702 and act 1704 of the method 1700 of FIG. 17. Because the package location 1900 includes vias 1906 proximate to the periphery of the package location 1900, at least a majority of the vias 1906 may be located outside the footprint of the microelectronic die 2102. For example, the vias 1906 of the printed circuit panel 1904 may be located outside the footprints of the microelectronic die 2102 of the plurality of microelectronic dice 2102.

Again returning to FIG. 17, the method 1700 may further involve singulating microelectronic device packages from the printed circuit panel, respective microelectronic device packages comprising at least one microelectronic die of the plurality of microelectronic dice and a portion of the printed circuit panel, as indicated at act 1706. More specifically, singulation may result in at least some of the microelectronic device packages having bond pads of the printed circuit panel located on a side of the at least some of the microelectronic device packages facing away from the microelectronic device, located along respective sides of peripheries of the at least some of the microelectronic device packages, and electrically connected to the vias, as indicated at act 1708. The act of singulation, and other packaging and processing tasks, may be accomplished by performing any of the actions described previously in connection with FIG. 9 and FIG. 16.

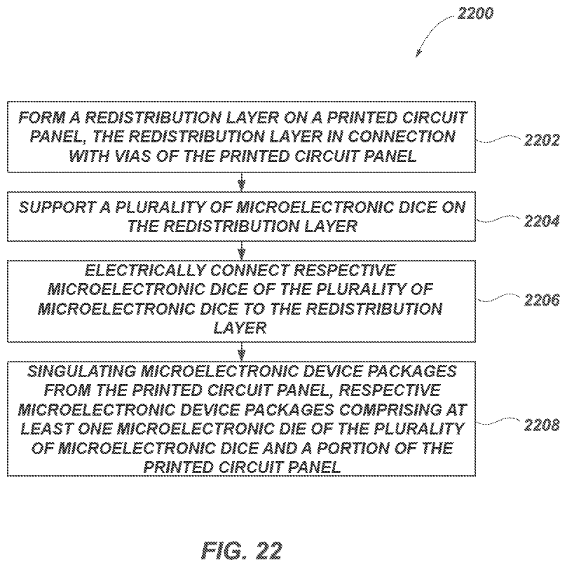

FIG. 22 is a flowchart of another, more specific method 2200 of packaging microelectronic devices. The method 2200 may involve, for example, forming a redistribution layer on a printed circuit panel, and the formed redistribution layer in electrical connection with vias of the printed circuit panel, as indicated at act 2202. A plurality of microelectronic dice may be supported on the redistribution layer, as reflected at act 2204. Respective microelectronic dice of the plurality of microelectronic dice may be electrically connected to the redistribution layer, as indicated at act 2206. Finally, microelectronic device packages may be singulated from the printed circuit panel, respective microelectronic device packages comprising at least one microelectronic die of the plurality of microelectronic dice and a portion of the printed circuit panel, as indicated at act 2208.

FIG. 22 shows an illustrative combination of acts performable when executing methods in accordance with this disclosure. Additional methods within the scope of this disclosure may involve the performance of any combination or subcombination of the acts described previously in this disclosure, where it is logically possible to do so, as expressly contemplated by the inventor.

Additional, nonlimiting examples within the scope of this disclosure include:

Example 1: A method, comprising: supporting a plurality of microelectronic dice on a printed circuit panel; electrically connecting respective microelectronic dice of the plurality of microelectronic dice to at least one via of the printed circuit panel; and singulating microelectronic device packages from the printed circuit panel, respective microelectronic device packages comprising at least one microelectronic die of the plurality of microelectronic dice and a portion of the printed circuit panel.

Example 2: The method of Example 1, comprising forming a redistribution layer on the printed circuit panel, the redistribution layer electrically connected to the at least one via, before supporting the plurality of microelectronic dice on the printed circuit panel, and wherein supporting the plurality of microelectronic dice on the printed circuit panel comprises supporting the plurality of microelectronic dice on the redistribution layer.

Example 3: The method of Example 2, wherein forming the redistribution layer comprises positioning electrically conductive material of the redistribution layer on regions of the printed circuit panel between vias of the printed circuit panel including the at least one via.

Example 4: The method of Example 2 or Example 3, wherein electrically connecting respective microelectronic dice of the plurality of microelectronic dice to the at least one via of the printed circuit panel comprises reflowing electrically conductive material extending from respective microelectronic dice of the plurality of microelectronic dice to the redistribution layer.

Example 5: The method of Example 4, wherein reflowing the electrically conductive material comprises directing energy emitted from a laser toward the electrically conductive material to reflow the electrically conductive material.

Example 6: The method of any one of Examples 1 through 5, comprising placing the plurality of microelectronic dice in flip-chip orientations when supporting the plurality of microelectronic dice on the printed circuit panel.

Example 7: The method of Example 1, comprising positioning active surfaces of the plurality of microelectronic dice sides of the plurality of microelectronic dice to face away from the printed circuit panel when supporting the plurality of microelectronic dice on the printed circuit panel.

Example 8: The method of Example 7, comprising forming a first redistribution layer on the printed circuit panel, the first redistribution layer in electrical connection with the at least one via, before supporting the plurality of microelectronic dice on the printed circuit panel, the first redistribution layer comprising distribution layer studs of electrically conductive material, the studs having a height above the printed circuit panel at least as great as a greatest thickness of any microelectronic die of the plurality of microelectronic dice, and wherein supporting the plurality of microelectronic dice on the printed circuit panel comprises supporting the plurality of microelectronic dice on portions of the redistribution layer between the studs.

Example 9: The method of Example 8, comprising placing a molding material around the plurality of microelectronic devices and around at least portions of the studs.

Example 10: The method of Example 9, comprising forming a second redistribution layer on the molding material, the second redistribution layer electrically connected to the distribution layer studs and electrically connected to the plurality of microelectronic devices.

Example 11: The method of Example 10, comprising placing a passivation material to cover the second redistribution layer.

Example 12: The method of any one of Examples 1 and 7 through 11, wherein singulating the microelectronic device packages from the printed circuit panel comprises singulating the microelectronic device packages such that at least some of the microelectronic device packages comprise bond pads of the printed circuit panel located on a side of at least some of the microelectronic device packages facing away from the microelectronic device, located along respective sides of peripheries of at least some of the microelectronic device packages, and electrically connected to the vias.

Example 13: The method of any one of Example 1 through 6, wherein singulating the microelectronic device packages from the printed circuit panel comprises singulating the microelectronic device packages such that at least some of the microelectronic device packages comprise bond pads arranged in a grid.

Example 14: The method of any one of Examples 1 or 7 through 11, wherein the at least one via is at least partially hollow and wherein singulating the microelectronic device packages from the printed circuit panel comprises cutting through the at least one via to form a castellation.

Example 15: A structure, comprising: a plurality of microelectronic dice supported on a printed circuit panel, the printed circuit panel comprising vias, subsets of the vias positioned for electrical connection to a respective microelectronic die of the plurality of microelectronic dice.

Example 16: The structure of Example 15, wherein footprints of the microelectronic dice of the plurality of microelectronic dice cover at least some of the vias of the printed circuit panel.

Example 17: The structure of Example 15, wherein respective vias of the subsets of the vias of the printed circuit panel are located outside the footprints of the microelectronic dice of the plurality of microelectronic dice.

Example 18: The structure of Example 17, wherein at least some of the vias are at least partially hollow.

Example 19: The structure of Example 17 or Example 18, wherein a pitch of the vias of the printed circuit panel is between 0.65 mm and 1 mm.

Example 20: The structure of any one of Examples 17 through 19, wherein dimensions of the printed circuit panel are 300 mm by 300 mm, 510 mm by 510 mm, 510 mm by 515 mm, 515 mm by 515 mm, or 600 mm by 600 mm.

Example 21: A method, comprising: forming a redistribution layer on a printed circuit panel, the redistribution layer electrically connected to vias of the printed circuit panel; supporting a plurality of microelectronic dice on the redistribution layer; electrically connecting respective microelectronic dice of the plurality of microelectronic dice to the redistribution layer; and singulating microelectronic device packages from the printed circuit panel, respective microelectronic device packages comprising at least one microelectronic die of the plurality of microelectronic dice and a portion of the printed circuit panel.

Utilizing a printed circuit panel, as disclosed herein, may, for example, enable panel-level packaging techniques to be performed without use of steel or glass carriers and without the need to perform carrier debond processes. Printed circuit panels may use lower-cost materials, may be easier to manufacture, may be lighter for a given rigidity, and may reduce the need to maintain stock of components susceptible to degradation over time (e.g., oxidation, without limitation). Further, printed circuit panels may also reduce mismatch in coefficient of thermal expansion between microelectronic devices and the underlying support, which may reduce warpage, facilitate easier handling, and reduce reliance on wasteful dummy chips to balance coefficient of thermal expansion. In addition, use of printed circuit panels may reduce or eliminate the need to account for device drift and misalignment during panelization.

While certain illustrative examples have been described in connection with the figures, those of ordinary skill in the art will recognize and appreciate that the scope of this disclosure is not limited to those examples explicitly shown and described in this disclosure. Rather, many additions, deletions, and modifications to the examples described in this disclosure may be made to produce examples within the scope of this disclosure, such as those specifically claimed, including legal equivalents. In addition, features from one disclosed example may be combined with features of another disclosed example while still being within the scope of this disclosure.

What is claimed is:

1. A method, comprising:
supporting a plurality of microelectronic dice on a printed circuit panel;
electrically connecting respective microelectronic dice of the plurality of microelectronic dice to at least one via of the printed circuit panel; and
singulating microelectronic device packages from the printed circuit panel, respective microelectronic device packages comprising at least one microelectronic die of the plurality of microelectronic dice and a portion of the printed circuit panel.

2. The method of claim 1, comprising forming a redistribution layer on the printed circuit panel, the redistribution layer electrically connected to the at least one via, before supporting the plurality of microelectronic dice on the printed circuit panel, and wherein supporting the plurality of microelectronic dice on the printed circuit panel comprises supporting the plurality of microelectronic dice on the redistribution layer.

3. The method of claim 2, wherein forming the redistribution layer comprises positioning electrically conductive material of the redistribution layer on regions of the printed circuit panel between vias of the printed circuit panel including the at least one via.

4. The method of claim 2, wherein electrically connecting respective microelectronic dice of the plurality of microelectronic dice to the at least one via of the printed circuit panel comprises reflowing electrically conductive material extending from respective microelectronic dice of the plurality of microelectronic dice to the redistribution layer.

5. The method of claim 4, wherein reflowing the electrically conductive material comprises directing energy emitted from a laser toward the electrically conductive material to reflow the electrically conductive material.

6. The method of claim 1, comprising placing the plurality of microelectronic dice in flip-chip orientations when supporting the plurality of microelectronic dice on the printed circuit panel.

7. The method of claim 1, comprising positioning active surfaces of the plurality of microelectronic dice sides of the plurality of microelectronic dice to face away from the printed circuit panel when supporting the plurality of microelectronic dice on the printed circuit panel.

8. The method of claim 7, comprising forming a first redistribution layer on the printed circuit panel, the first redistribution layer in electrical connection with the at least one via, before supporting the plurality of microelectronic dice on the printed circuit panel, the first redistribution layer comprising distribution layer studs of electrically conductive material, the studs having a height above the printed circuit panel at least as great as a greatest thickness of any microelectronic die of the plurality of microelectronic dice, and wherein supporting the plurality of microelectronic dice on the printed circuit panel comprises supporting the plurality of microelectronic dice on portions of the redistribution layer between the studs.

9. The method of claim 8, comprising placing a molding material around the plurality of microelectronic devices and around at least portions of the studs.

10. The method of claim 9, comprising forming a second redistribution layer on the molding material, the second redistribution layer electrically connected to the distribution layer studs and electrically connected to the plurality of microelectronic devices.

11. The method of claim 10, comprising placing a passivation material to cover the second redistribution layer.

12. The method of claim 1, wherein singulating the microelectronic device packages from the printed circuit panel comprises singulating the microelectronic device packages such that at least some of the microelectronic device packages comprise bond pads of the printed circuit panel located on a side of at least some of the microelectronic device packages facing away from the microelectronic device, located along respective sides of peripheries of at least some of the microelectronic device packages, and electrically connected to respective vias of the printed circuit panel including the at least one via.

13. The method of claim 1, wherein singulating the microelectronic device packages from the printed circuit panel comprises singulating the microelectronic device packages such that at least some of the microelectronic device packages comprise bond pads arranged in a grid.

14. The method of claim 1, wherein the at least one via is at least partially hollow and wherein singulating the microelectronic device packages from the printed circuit panel comprises cutting through the at least one via to form a castellation.

15. A structure, comprising:
a plurality of microelectronic dice supported on a printed circuit panel, the printed circuit panel comprising vias, subsets of the vias positioned for electrical connection to a respective microelectronic die of the plurality of microelectronic dice.

16. The structure of claim 15, wherein footprints of the microelectronic dice of the plurality of microelectronic dice cover at least some of the vias of the printed circuit panel.

17. The structure of claim 15, wherein respective vias of the subsets of the vias of the printed circuit panel are located outside footprints of the microelectronic dice of the plurality of microelectronic dice.

18. The structure of claim 17, wherein at least some of the vias are at least partially hollow.

19. The structure of claim 17, wherein a pitch of the vias of the printed circuit panel is between 0.65 mm and 1 mm.

20. The structure of claim 17, wherein dimensions of the printed circuit panel are 300 mm by 300 mm, 510 mm by 510 mm, 510 mm by 515 mm, 515 mm by 515 mm, or 600 mm by 600 mm.

21. A method, comprising:
forming a redistribution layer on a printed circuit panel, the redistribution layer electrically connected to vias of the printed circuit panel;
supporting a plurality of microelectronic dice on the redistribution layer;
electrically connecting respective microelectronic dice of the plurality of microelectronic dice to the redistribution layer; and
singulating microelectronic device packages from the printed circuit panel, respective microelectronic device packages comprising at least one microelectronic die of the plurality of microelectronic dice and a portion of the printed circuit panel.
